(19) United States
(12) Patent Application Publication
(10) Pub. No.: US 2026/0191053 A1
(43) Pub. Date: Jul. 2, 2026

(54) SEMICONDUCTOR PACKAGE

(71) Applicant: SAMSUNG ELECTRONICS CO., LTD., Suwon-si (KR)

(72) Inventor: Soon Chul LEE, Suwon-si (KR)

(73) Assignee: SAMSUNG ELECTRONICS CO., LTD., Suwon-si (KR)

(21) Appl. No.: 19/307,804

(22) Filed: Aug. 22, 2025

(30) Foreign Application Priority Data
Dec. 27, 2024 (KR) 10-2024-0198300

(51) Int. Cl. H01L 23/498; H01L 23/31; H01L 23/538; H01L 25/065; H01L 25/18; H10B 80/00; H10D 80/30

(52) U.S. Cl. CPC H10W 70/65; H10W 70/611; H10W 70/66; H10B 80/00; H10D 80/30; H10W 74/117; H10W 90/00; H10W 90/24; H10W 90/722; H10W 90/724; H10W 90/752; H10W 90/754

(57) ABSTRACT

A semiconductor package for improved yield and reliability includes a substrate, a first pad array disposed on the substrate and including a plurality of pads repeatedly arranged in a first direction in a plan view, and a second pad array disposed on the substrate and spaced apart from the first pad array in a second direction perpendicular to the first direction, and including a plurality of pads repeatedly arranged in the first direction. The first pad array includes first second pads alternately arranged with each other, the second pad array includes third fourth pads alternately arranged with each other, a width in the first direction of the first pad is different from a width in the first direction of the second pad, and a width in the first direction of the third pad is different from a width in the first direction of the fourth pad.

### CROSS-REFERENCE TO RELATED APPLICATION

This application claims priority from Korean Patent Application No. 10-2024-0198300 filed on Dec. 27, 2024 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a semiconductor package.

### 2. Description of Related Art

A semiconductor package is provided by mounting a semiconductor chip on a package substrate. The package substrate mechanically supports a semiconductor chip and electrically connects the semiconductor chip to an external element. During a process of manufacturing the semiconductor package, a molding process is performed to protect the semiconductor chip mounted on the package substrate. The semiconductor chip may be surrounded with an epoxy mold compound (EMC) in a molding process and thus be protected from an outside.

When performing the molding process of applying the epoxy mold compound in a liquid state on a substrate, there is a need for a scheme capable of more easily applying the epoxy mold compound into between pads disposed on the substrate.

### SUMMARY

A purpose of the present disclosure is to provide a semiconductor package having improved yield and reliability.

The technical purposes of the present disclosure are not limited to the technical purposes as mentioned above, and other technical purposes as not mentioned may be clearly understood by those skilled in the art from descriptions as set forth below.

According to an aspect of the present disclosure, there is provided a semiconductor package comprising a substrate, a first pad array disposed on the substrate and including a plurality of pads repeatedly arranged in a first direction in a plan view of the semiconductor package, and a second pad array disposed on the substrate and spaced apart from the first pad array in a second direction perpendicular to the first direction in the plan view, and including a plurality of pads repeatedly arranged in the first direction in the plan view, in which the first pad array includes first pads and second pads alternately arranged with each other, the second pad array includes third pads and fourth pads alternately arranged with each other, a width in the first direction of one of the first pads is different from a width in the first direction of one of the second pads, a width in the first direction of one of the third pads is different from a width in the first direction of one of the fourth pads.

According to another aspect of the present disclosure, there is provided a semiconductor package comprising a substrate, a first pad array disposed on the substrate and including a plurality of first pads repeatedly arranged in a first direction in a plan view of the semiconductor package, and a second pad array disposed on the substrate and spaced apart from the first pad array in a second direction perpendicular to the first direction in the plan view, and including a plurality of second pads repeatedly arranged in the first direction in the plan view, in which a width in the first direction of each of the plurality of first pads is greater than a width in the first direction of any one of the second pads, a width in the second direction of each of the plurality of first pads is smaller than a width in the second direction of any one of the second pads.

According to another aspect of the present disclosure, there is provided a semiconductor package comprising a package substrate including a wiring structure and including upper and lower surfaces opposite to each other, an external connection terminal disposed on the lower surface of the package substrate, a semiconductor chip flip-chip bonded to the upper surface of the package substrate, a substrate pad disposed on the upper surface of the package substrate, a chip pad disposed on a lower surface of the semiconductor chip and a connection member disposed between the substrate pad and the chip pad, in which the substrate pad includes a first pad array including a plurality of pads repeatedly arranged in a first direction in a plan view of the semiconductor package and a second pad array spaced apart from the first pad array in a second direction perpendicular to the first direction in the plan view and including a plurality of pads repeatedly arranged in the first direction in the plan view, the first pad array includes first pads and second pads alternately arranged with each other, the second pad array includes third pads and fourth pads alternately arranged with each other, a width in the first direction of the first pad is different from a width in the first direction of the second pad, and a width in the first direction of the third pad is different from a width in the first direction of the fourth pad.

It should be noted that the effects of the present disclosure are not limited to those described above, and other effects of the present disclosure will be apparent from the following description.

### BRIEF DESCRIPTION OF DRAWINGS

The above and other aspects and features of the present disclosure will become more apparent by describing in detail embodiments thereof with reference to the attached drawings, in which:

FIG. 1 is a plan view for illustrating a semiconductor package according to some embodiments of the present disclosure.

FIG. 2 is a plan view illustrating a semiconductor package according to another embodiment of the present disclosure.

FIG. 3 is a plan view illustrating a semiconductor package according to still another embodiment of the present disclosure.

FIG. 4 is a plan view illustrating a semiconductor package according to still yet another embodiment of the present disclosure.

FIG. 5 is a cross-sectional view of a semiconductor package according to still yet another embodiment of the present disclosure.

FIG. 6 is a cross-sectional view of a semiconductor package according to still yet another embodiment of the present disclosure.

FIG. 7 is a cross-sectional view of a semiconductor package according to still yet another embodiment of the present disclosure.

FIG. 8 is a cross-sectional view of a semiconductor package according to still yet another embodiment of the present disclosure.

FIG. 9 is a cross-sectional view of a semiconductor package according to still yet another embodiment of the present disclosure.

FIG. 10 is a cross-sectional view of a semiconductor package according to still yet another embodiment of the present disclosure.

FIG. 11 is a cross-sectional view of a semiconductor package according to still yet another embodiment of the present disclosure.

### DETAILED DESCRIPTIONS

Although the first, second, and the like are used herein to describe various elements or components, it is obvious that these elements or components are not limited by these terms. These terms are merely used to distinguish one element or component from another element or component. Accordingly, it is obvious that the first element or component as mentioned below may be the second element or component within the technical idea of the present disclosure.

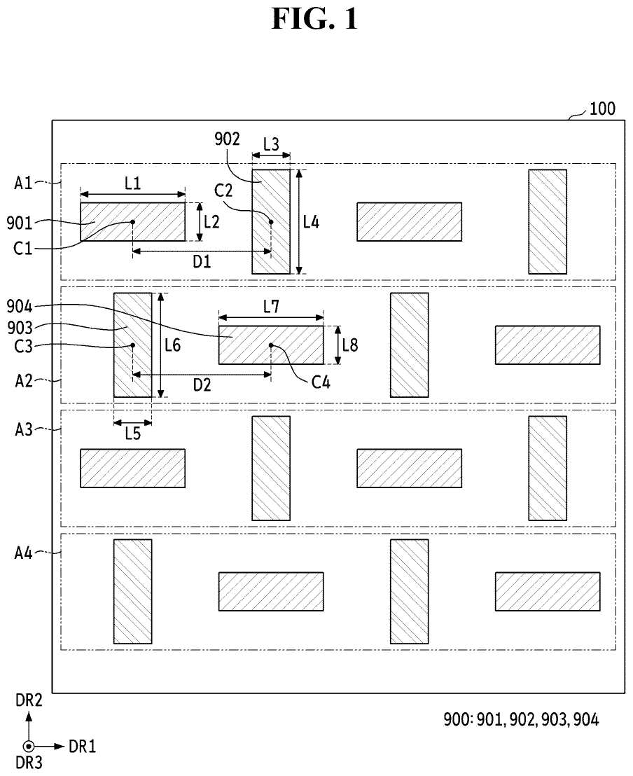

FIG. 1 is a plan view for illustrating a semiconductor package according to some embodiments of the present disclosure. Referring to FIG. 1, a semiconductor package according to some embodiments of the present disclosure may include a substrate 100, a first pad array A1, a second pad array A2, a third pad array A3, and a fourth pad array A4.

The substrate 100 extends in a first direction DR1 and a second direction DR2 different from the first direction. As used herein, the first direction DR1 and the second direction DR2 may intersect each other. The first direction DR 1 and the second direction DR 2 may be substantially perpendicular to each other. The first direction DR 1 and the second direction DR 2 may be parallel to an upper surface of the substrate 100. A third direction DR3 may intersect the first direction DR1 and the second direction DR2. The third direction DR3 may be substantially perpendicular to the first direction DR1 and the second direction DR2. The third direction DR 3 may be a direction perpendicular to the upper surface of the substrate 100.

The substrate 100 may be a semiconductor package substrate on which a semiconductor chip is mounted. The substrate 100 may be, for example, at least one of a printed circuit board (PCB), a flip chip ball grid array (FCBGA), a flip chip chip scale package (FCCSP), and an interposer. However, the present disclosure is not limited thereto.

The first pad array A1, the second pad array A2, the third pad array A3, and the fourth pad array A4 may be spaced apart from each other in the second direction DR2. Each of the first pad array A1, the second pad array A2, the third pad array A3, and the fourth pad array A4 may include a plurality of pads repeatedly arranged in the first direction DR1. For reference, FIG. 1 illustrates a case in which the four pad arrays A1, A2, A3, and A4 are disposed. However, the present disclosure is not limited thereto. In another example, the semiconductor package according to another embodiment of the present disclosure may include dozens of pad arrays.

The first pad array A1 may include a plurality of first pads 901 and a plurality of second pads 902. The third pad array A3 may include the same pad arrangement as that of the first pad array A1. Since the description of the third pad array A3 is the same as the description of the first pad array A1, the description of the third pad array A3 will be replaced with the description of the first pad array A1 in the following description.

For reference, FIG. 1 illustrates a case in which the first pad array A1 includes four substrate pads. However, the present disclosure is not limited thereto. In another example, the first substrate array according to another embodiment of the present disclosure may include dozens of substrate pads.

The first pad array A1 may include a plurality of first pads 901 and a plurality of second pads 902 that are repeatedly arranged in the first direction DR1. The first pads 901 and the second pads 902 may be alternately arranged with each other. For example, the second pad 902 may be disposed between adjacent ones of the plurality of first pads 901. In another example, the first pad 901 may be disposed between adjacent ones of the plurality of second pads 902.

Although spacings between the first pads 901 and the second pads 902 are shown to be equal to each other, an embodiment of the present disclosure is not limited thereto. In another example, the spacings between the first pads 901 and the second pads 902 may become smaller or larger as the arrangement thereof extends in the first direction DR 1.

A width L1 of the first pad 901 in the first direction DR1 may be greater than a width L3 of the second pad 902 in the first direction DR1. A width L2 of the first pad 901 in the second direction DR2 may be smaller than a width L4 of the second pad 902 in the second direction DR2. The width L1 of the first pad 901 in the first direction DR1 may be substantially equal to the width L4 of the second pad 902 in the second direction DR2. The width L2 of the first pad 901 in the second direction DR2 may be equal to the width L3 of the second pad 902 in the first direction DR1.

As used herein, the expression “substantially equal” may refer to having the same measurement value relative to the measurement compared therewith, as will be appreciated by those of skill in the art, and allows for approximations, inaccuracies and limits of measurement under the relevant circumstances. In one or more aspects, the terms “substantially,” “about,” and “approximately” may provide an industry-accepted tolerance for their corresponding terms and/or relativity between items, such as a tolerance of ±1%, ±5%, or ±10% of the actual value stated, and other suitable tolerances.

A central point C1 of the width L1 of the first pad 901 in the first direction DR1 may coincide with a central point C1 of the width L2 of the first pad 901 in the second direction DR2. Hereinafter, each of the center point C1 of the width L1 of the first pad 901 in the first direction DR1 and the center point C1 of the width L2 of the first pad 901 in the second direction DR2 is referred to as a first center point C1.

A central point C2 of the width L3 of the second pad 902 in the first direction DR1 may coincide with a central point C2 of the width L4 of the second pad 902 in the second direction DR2. Hereinafter, each of the center point C2 of the width L3 of the second pad 902 in the first direction DR1 and the center point C2 of the width L4 of the second pad 902 in the second direction DR2 is referred to as a second center point C2.

The second pad array A2 may include a plurality of third pads 903 and a plurality of fourth pads 904. The fourth pad array A4 may include the same pad arrangement as that of the second pad array A2. Since the description of the fourth pad array A4 is the same as the description of the second pad array A2, the description of the fourth pad array A4 will be replaced with the description of the second pad array A2 in the following description.

For reference, FIG. 1 illustrates a case in which the second pad array A2 includes four substrate pads. However, the present disclosure is not limited thereto. In another example, the second substrate array according to another embodiment of the present disclosure may include dozens of substrate pads.

The second pad array A2 may include a plurality of third pads 903 and a fourth pad 904 that are repeatedly arranged in the first direction DR1. The third pads 903 and the fourth pads 904 may be alternately arranged with each other. For example, the fourth pad 904 may be disposed between adjacent ones of the plurality of third pads 903. In another example, the third pad 903 may be disposed between adjacent ones of the plurality of fourth pads 904.

Although the spacings between the third pad 903 and the fourth pad 904 are shown to be equal to each other, an embodiment of the present disclosure is not limited thereto. In another example, the spacings between the third pad 903 and the fourth pad 904 may become smaller or larger as the arrangement extends in the first direction DR1.

A width L5 of the third pad 903 in the first direction DR1 may be smaller than a width L7 of the fourth pad 904 in the first direction DR1. A width L6 of the third pad 903 in the second direction DR2 may be greater than a width L8 of the fourth pad 904 in the second direction DR2. The width L5 of the third pad 903 in the first direction DR1 may be substantially equal to the width L8 of the fourth pad 904 in the second direction DR2. The width L6 of the third pad 903 in the second direction DR2 may be substantially equal to the width L7 of the fourth pad 904 in the first direction DR1.

A central point C3 of the width L5 of the third pad 903 in the first direction DR1 may coincide with a central point C3 of the width L6 of the third pad 903 in the second direction DR2. Hereinafter, each of the center point C3 of the width L5 of the third pad 903 in the first direction DR1 and the center point C3 of the width L6 of the third pad 903 in the second direction DR2 is referred to as a third center point C3.

A central point C4 of the width L7 of the fourth pad 904 in the first direction DR1 may coincide with a central point C4 of the width L8 of the fourth pad 904 in the second direction DR2. Hereinafter, each of the center point C4 of the width L7 of the fourth pad 904 in the first direction DR1 and the center point C4 of the width L8 of the fourth pad 904 in the second direction DR2 is referred to as a fourth center point C4.

The first center point C1 and the second center point C2 may be aligned with each other along the same line extending in the first direction DR1. The third center point C3 and the fourth center point C4 may be aligned with each other along the same line extending in the first direction DR1. The first center point C1 and the third center point C3 may be aligned with each other along the same line extending in the second direction DR2. The second center point C2 and the fourth center point C4 may be aligned with each other along the same line extending in the second direction DR2.

One of ordinary skill in the art would understand that the expression “(be) aligned ... along a same line” refers to being aligned with the component compared therewith along the same line by allowing process errors, positional deviations, and/or measurement errors that may occur in a manufacturing process, and the range thereof may be widely accepted in the art (for example, ±1%, ±5%, or ±10%, but not limited thereto).

A length D1 in the first direction DR1 between the first center point C1 and the second center point C2 may be substantially equal to a length D2 in the first direction DR1 between the third center point C3 and the fourth center point C4. However, the present disclosure is not limited thereto. In another example, the length D1 in the first direction DR1 between the first center point C1 and the second center point C2 may be greater than the length D2 in the first direction DR1 between the third center point C3 and the fourth center point C4.

Since the width L1 of the first pad 901 in the first direction DR1 is greater than the width L3 of the second pad 902 in the first direction DR1, a spacing between the first pad 901 and the second pad 902 may be greater than a spacing between the first pad 901 and the second pad 902 in a case where the width L1 of the first pad 901 in the first direction DR1 and the width L3 of the second pad 902 in the first direction DR1 are substantially equal to each other.

Since the width L1 of the first pad 901 in the first direction DR1 is greater than the width L3 of the second pad 902 in the first direction DR1, a spacing between the first pad 901 and the second pad 902 may be greater than a spacing between the first pad 901 and the second pad 902 in a case where the width L1 of the first pad 901 in the first direction DR1 and the width L3 of the second pad 902 in the first direction DR1 are substantially equal to each other.

In addition, since the width L5 of the third pad 903 in the first direction DR1 is smaller than the width L7 of the fourth pad 904 in the first direction DR1, a spacing between the third pad 903 and the fourth pad 904 may be greater than a spacing between the third pad 903 and the fourth pad 904 in a case where the width L5 of the third pad 903 in the first direction DR1 and the width L7 of the fourth pad 904 in the first direction DR1 are substantially equal to each other.

Therefore, when a liquid encapsulant is applied in a subsequent process, the encapsulant may be easily introduced into between adjacent ones of the plurality of substrate pads. For example, when the epoxy mold compound (EMC) is applied in the subsequent process, the epoxy mold compound may be easily introduced into between adjacent ones of the plurality of substrate pads included in each of the first pad array A1, the second pad array A2, the third pad array A3, and the fourth pad array A4.

Each of the first pad 901, the second pad 902, the third pad 903, and the fourth pad 904 may include at least one of gold (Au), silver (Ag), copper (Cu), nickel (Ni), and aluminum (Al).

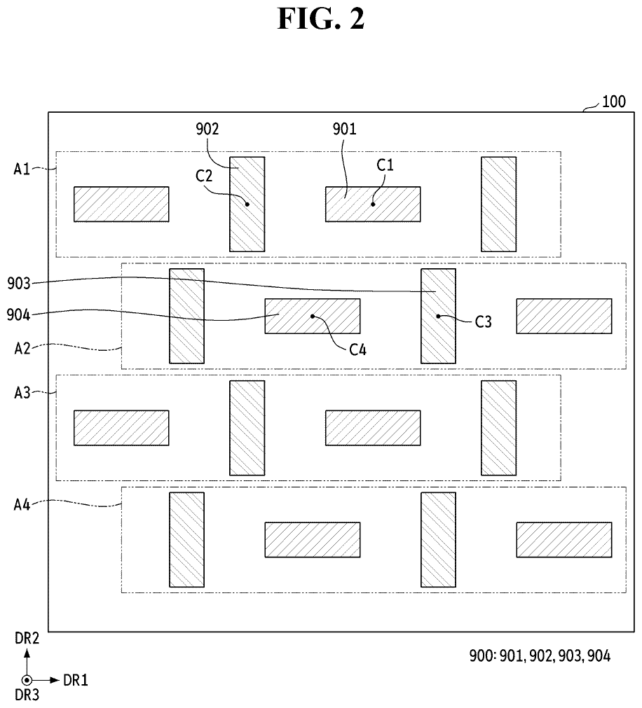

FIG. 2 is a plan view illustrating a semiconductor package according to another embodiment of the present disclosure. For convenience of description, differences thereof from those as described in FIG. 1 will be mainly described with reference to FIG. 2.

Referring to FIG. 2, a semiconductor package according to another embodiment may include the substrate 100, the first pad array A1, the second pad array A2, the third pad array A3, and the fourth pad array A4.

The first center point C1 and the second center point C2 may be aligned with each other along the same line extending in the first direction DR1. The third center point C3 and the fourth center point C4 may be aligned with each other along the same line extending in the first direction DR1. The first center point C1 and the third center point C3 may not overlap each other in the second direction DR2. The first center point C1 and the fourth center point C4 may not overlap each other in the second direction DR2. The second center point C2 and the third center point C3 may not overlap each other in the second direction DR2. The second center point C2 and the fourth center point C4 may not overlap each other in the second direction DR2.

The first central point C1 and the third central point C3 may not overlap each other in the second direction DR2, the first central point C1 and the fourth central point C4 may not overlap each other in the second direction DR2, the second central point C2 and the third central point C3 may not overlap each other in the second direction DR2, and the second central point C2 and the fourth central point C4 may not overlap each other in the second direction DR2. Therefore, when a liquid encapsulant is applied in a subsequent process, the encapsulant may be easily introduced into between adjacent ones of the plurality of substrate pads. For example, when the epoxy mold compound is applied in the subsequent process, the epoxy mold compound may be easily introduced into between the first pad array A1, the second pad array A2, the third pad array A3, and the fourth pad array A4.

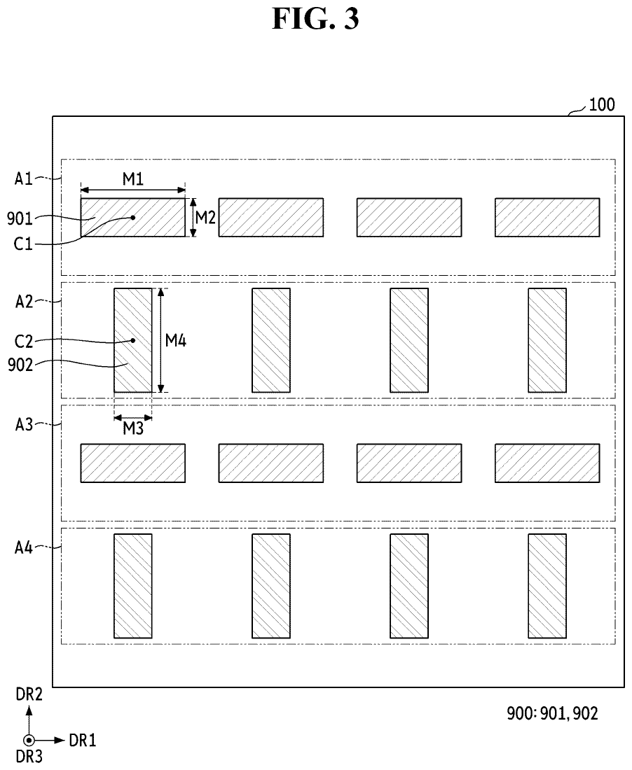

FIG. 3 is a plan view illustrating a semiconductor package according to still another embodiment of the present disclosure. For convenience of description, differences thereof from those described with reference to FIG. 1 will be mainly described with reference to FIG. 3.

Referring to FIG. 3, a semiconductor package according to still another embodiment may include the substrate 100, the first pad array A1, the second pad array A2, the third pad array A3, and the fourth pad array A4.

The first pad array A1 may include the plurality of first pads 901. The third pad array A3 may include the same pad arrangement as that of the first pad array A1. Since the description of the third pad array A3 is the same as the description of the first pad array A1, the description of the third pad array A3 will be replaced with the description of the first pad array A1 in the following description.

Although the spacings between adjacent ones of the plurality of first pads 901 are shown to be equal to each other, an embodiment of the present disclosure is not limited thereto. In another example, the spacings between adjacent ones of the plurality of first pads 901 may become smaller or larger as the arrangement extends in the first direction DR 1.

The central point C 1 of the width M 1 of the first pad 901 in the first direction DR 1 may coincide with the central point C 1 of the width M 2 of the first pad 901 in the second direction DR 2. Hereinafter, each of the center point C1 of the width M1 of the first pad 901 in the first direction DR1 and the center point C1 of the width M2 of the first pad 901 in the second direction DR2 is referred to as a first center point C1.

The second pad array A2 may include the plurality of second pads 902. The fourth pad array A4 may include the same pad arrangement as that of the second pad array A2. Since the description of the fourth pad array A4 is the same as the description of the second pad array A2, the description of the fourth pad array A4 will be replaced with the description of the second pad array A2 in the following description.

Although the spacings between adjacent ones of the plurality of second pads 902 are shown to be equal to each other, an embodiment of the present disclosure is not limited thereto. In another example, the spacings between adjacent ones of the plurality of second pads 902 may become smaller or larger as the arrangement extends in the first direction DR 1.

The central point C2 of the width M1 of the second pad 902 in the first direction DR1 may coincide with the central point C2 of the width M2 of the second pad 902 in the second direction DR2. Hereinafter, each of the center point C2 of the width M1 of the second pad 902 in the first direction DR1 and the center point C2 of the width M2 of the second pad 902 in the second direction DR2 is referred to as a second center point C2.

All of the first central points C1 of the plurality of first pads 901 may be aligned with each other in the same line extending in the first direction DR1. All of the second center points C2 of the plurality of second pads 902 may be aligned with each other the same line extending in the first direction DR1. The first center point C1 and the second center point C2 may be aligned with each other in the same line extending in the second direction DR2.

The width M1 of the first pad 901 in the first direction DR1 may be greater than the width M3 of the second pad 902 in the first direction DR1. The width M2 of the first pad 901 in the second direction DR2 may be smaller than the width M4 of the second pad 902 in the second direction DR2. The width M1 of the first pad 901 in the first direction DR1 may be substantially equal to the width M4 of the second pad 902 in the second direction DR2. The width M2 of the first pad 901 in the second direction DR2 may be substantially equal to the width M3 of the second pad 902 in the first direction DR1.

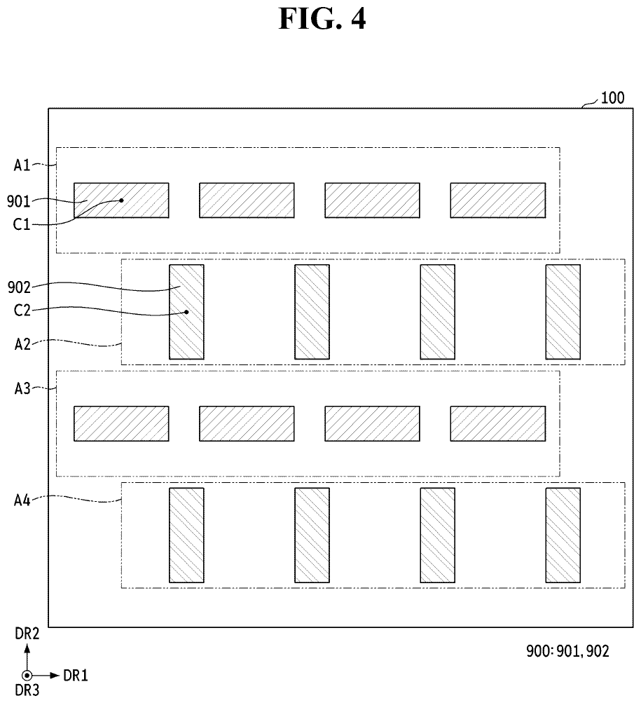

FIG. 4 is a plan view illustrating a semiconductor package according to still yet another embodiment of the present disclosure. For convenience of description, differences thereof from those described with reference to FIG. 3 will be mainly described with reference to FIG. 4.

Referring to FIG. 4, a semiconductor package according to still yet another embodiment may include the substrate 100, the first pad array A1, the second pad array A2, the third pad array A3, and the fourth pad array A4.

The first center point C1 and the second center point C2 may not overlap each other in the second direction DR2. The first center point C1 and the second center point C2 may not overlap each other in the second direction DR2. Therefore, when a liquid encapsulant is applied in a subsequent process, the encapsulant may be easily introduced into between adjacent ones of the plurality of substrate pads. For example, when the epoxy mold compound is applied in the subsequent process, the epoxy mold compound may be easily introduced into between the first pad array A1, the second pad array A2, the third pad array A3, and the fourth pad array A4.

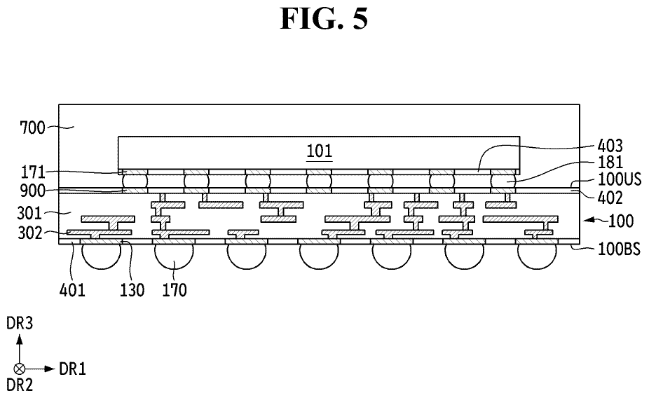

FIG. 5 is a cross-sectional view of a semiconductor package according to still yet another embodiment of the present disclosure. For convenience of description, differences thereof from those described with reference to FIG. 1 will be mainly described with reference to FIG. 5.

Referring to FIG. 5, a semiconductor package according to some further embodiments may include the substrate 100, a plurality of connection members 180, a first semiconductor chip 101, and an encapsulant 700.

The substrate 100 may include an insulating layer 301, a metal wiring layer 302, a bonding pad 130, an external connection terminal 170, a first substrate pad 900, a first passivation film 401, a second passivation film 402, and the encapsulant 700.

The substrate 100 may include a lower surface 100BS and an upper surface 100US opposite to each other. A surface of the substrate 100 may be covered with a solder resist. That is, each of the first passivation film 401 and the second passivation film 402 formed on the surface of the substrate 100 may be the solder resist. However, the technical idea of the present disclosure is not limited thereto.

The substrate 100 is illustrated as a single layer, but this is only for convenience of illustration. For example, the substrate 100 may be composed of multiple layers such that multiple metal wiring layers 302 may be formed therein.

The insulating layer 301 is illustrated as being a single layer, but this is only for convenience of illustration. For example, it is obvious that the insulating layer 301 may be composed of multiple layers such that multiple wiring patterns may be formed therein.

The metal wiring layer 302 may be formed in the insulating layer 301. An electrical signal may flow via the metal wiring layer 302. In other words, the metal wiring layer 302 may be used to electrically connect the substrate 100 to other components.

The bonding pad 130 may be formed on the lower surface 100BS of the substrate 100. The external connection terminal 170 may be attached on the bonding pad 130. The external connection terminal 170 may include a solder ball or a solder bump. The external connection terminal 170 may have, for example, a spherical shape or an elliptical shape. However, the present disclosure is not limited thereto. The number, spacing, arrangement, shape, and the like of the external connection terminals 170 are not limited to those shown, and may vary depending on the design. The external connection terminal 170 may include, for example, tin (Sn), indium (In), bismuth (Bi), antimony (Sb), copper (Cu), silver (Ag), zinc (Zn), lead (Pb), or a combination thereof. However, the present disclosure is not limited thereto.

The external connection terminal 170 may electrically connect the metal wiring layer 302 to an external device. Accordingly, the external connection terminal 170 may provide an electrical signal to the metal wiring layer 302 or may provide an electrical signal provided from the metal wiring layer 302 to the external device.

The substrate pad 900 may be formed on the upper surface 100US of the substrate. The substrate pad 900 may correspond to the plurality of pad arrays A1, A2, A3, and A4 of FIG. 1. For example, the substrate pad 900 may correspond to the first pad array A1, the second pad array A2, the third pad array A3, and the fourth pad array A4.

The first semiconductor chip 101 may be mounted on the upper surface 100US of the substrate. The first semiconductor chip 101 may be a logic semiconductor chip. The logic semiconductor chip may be, for example, an application processor (AP) such as a central processing unit (CPU), a graphic processing unit (GPU), a field-programmable gate array (FPGA), a digital signal processor, an encryption processor, a microprocessor, a microcontroller, an application-specific IC (ASIC), etc. However, the present disclosure is not limited thereto.

In another example, the first semiconductor chip 101 may be a memory semiconductor chip. The memory semiconductor chip may be, for example, a volatile memory such as a dynamic random access memory (DRAM) or a static random access memory (SRAM). Alternatively, the memory semiconductor chip included in the first semiconductor chip 101 may be a non-volatile memory such as a flash memory, a phase-change random access memory (PRAM), a magnetic random access memory (MRAM), a ferroelectric random access memory (FeRAM), or a resistive random access memory (RRAM).

The third passivation layer 403 may be formed on a lower surface of the first semiconductor chip 101. The third passivation film 403 may be a solder resist. However, the technical idea of the present disclosure is not limited thereto.

The first chip pad 171 may electrically connect the first semiconductor chip 101 to the substrate 100. The first connection member 181 may be disposed between the first semiconductor chip 101 and the substrate 100. In other words, the first semiconductor chip 101 and the substrate 100 may be connected to each other via the first connection member 181. The first chip pad 171 disposed on the lower surface of the first semiconductor chip 101 and the first substrate pad 900 disposed on the upper surface 100US of the substrate 100 may be electrically connected to each other via the first connection member 181. Each of the first chip pad 171, the first connection member 181, and the first substrate pad 900 may include a conductive material. For example, each of the first chip pad 171, the first connection member 181, and the first substrate pad 900 may include gold (Au), silver (Ag), copper (Cu), nickel (Ni), or aluminum (Al).

The encapsulant 700 may cover both the upper surface of the substrate 100 and the upper surface of the first semiconductor chip 101. The encapsulant 700 may include, for example, an insulating polymer material such as an epoxy mold compound. However, the present disclosure is not limited thereto.

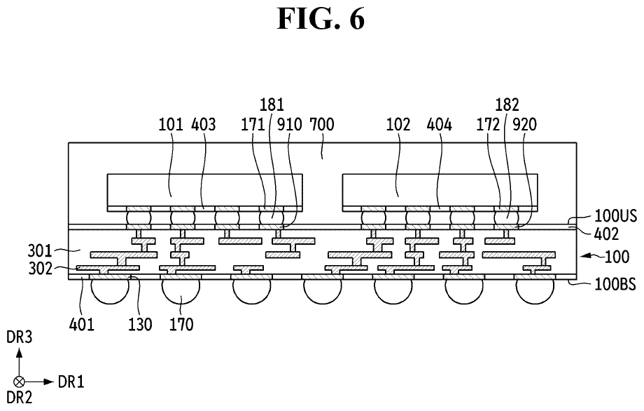

FIG. 6 is a cross-sectional view of a semiconductor package according to still yet another embodiment of the present disclosure. For convenience of description, differences thereof from those described with reference to FIG. 5 will be mainly described with reference to FIG. 6.

Referring to FIG. 6, a semiconductor package according to some further embodiments may include a substrate 100, a plurality of first connection members 181, a plurality of second connection members 182, a first semiconductor chip 101, a second semiconductor chip 102, and an encapsulant 700. For reference, the first substrate pad 910 disposed on the lower surface of the first semiconductor chip 101 may correspond to the substrate pad 900 of FIG. 5. In addition, the second substrate pad 920 disposed on the lower surface of the second semiconductor chip 102 may correspond to the first substrate pad 900 of FIG. 5.

The second semiconductor chip 102 may be mounted on the upper surface 100US of the substrate. The second semiconductor chip 102 may be a logic semiconductor chip. The logic semiconductor chip may be, for example, an application processor (AP) such as a central processing unit (CPU), a graphic processing unit (GPU), a field-programmable gate array (FPGA), a digital signal processor, an encryption processor, a microprocessor, a microcontroller, an application-specific IC (ASIC), etc. However, the present disclosure is not limited thereto.

In another example, the second semiconductor chip 102 may be a memory semiconductor chip. The memory semiconductor chip may be, for example, a volatile memory such as a dynamic random access memory (DRAM) or a static random access memory (SRAM). Alternatively, the memory semiconductor chip included in the second semiconductor chip 102 may be a non-volatile memory such as a flash memory, a phase-change random access memory (PRAM), a magnetic random access memory (MRAM), a ferroelectric random access memory (FeRAM), or a resistive random access memory (RRAM).

A fourth passivation layer 404 may be formed on the lower surface of the second semiconductor chip 102. The fourth passivation film 404 may be a solder resist. However, the technical idea of the present disclosure is not limited thereto.

The second chip pad 172 may electrically connect the second semiconductor chip 102 to the substrate 100. The second connection member 182 may be disposed between the second semiconductor chip 102 and the substrate 100. In other words, the second semiconductor chip 102 and the substrate 100 may be connected to each other via the second connection member 182. The second chip pad 172 disposed on the lower surface of the second semiconductor chip 102 and the second substrate pad 920 disposed on the upper surface 100US of the substrate 100 may be electrically connected to each other via a second connection member 182. Each of the second chip pad 172, the second connection member 182, and the second substrate pad 920 may include a conductive material. For example, each of the second chip pad 172, the second connection member 182, and the second substrate pad 920 may include gold (Au), silver (Ag), copper (Cu), nickel (Ni), or aluminum (Al).

The encapsulant 700 may cover all of the upper surface of the substrate 100, the upper surface of the first semiconductor chip 101, and the upper surface of the second semiconductor chip 102.

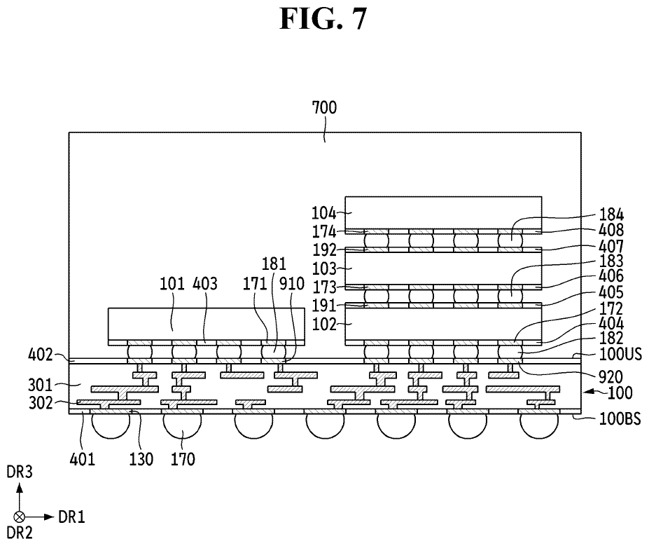

FIG. 7 is a cross-sectional view of a semiconductor package according to still yet another embodiment of the present disclosure. For convenience of description, following description will be made based on differences thereof from those as described above with reference to FIG. 6. For reference, the first substrate pad 910 disposed on the lower surface of the first semiconductor chip 101 may correspond to the substrate pad 900 of FIG. 5. In addition, the second substrate pad 920 disposed on the lower surface of the second semiconductor chip 102 may correspond to the first substrate pad 900 of FIG. 5.

Referring to FIG. 7, a semiconductor package according to some further embodiments may include the substrate 100, a plurality of first connection members 181, a plurality of second connection members 182, a plurality of third connection members 183, a plurality of fourth connection members 184, the first semiconductor chip 101, the second semiconductor chip 102, a third semiconductor chip 103, the fourth semiconductor chip 104, and the encapsulant 700.

The third semiconductor chip 103 and the fourth semiconductor chip 104 may be disposed on the second semiconductor chip 102. Each of the third semiconductor chip 103 and the fourth semiconductor chip 104 may be a logic semiconductor chip. The logic semiconductor chip may be, for example, an AP (Application Processor) such as a central processing unit (CPU), a graphic processing unit (GPU), a field-programmable gate array (FPGA), a digital signal processor, an encryption processor, a microprocessor, a microcontroller, an application-specific IC (ASIC), etc. However, the present disclosure is not limited thereto.

In another example, each of the third semiconductor chip 103 and the fourth semiconductor chip 104 may be a memory semiconductor chip. The memory semiconductor chip may be, for example, a volatile memory such as a dynamic random access memory (DRAM) or a static random access memory (SRAM). Alternatively, the memory semiconductor chip included in each of the third semiconductor chip 103 and the fourth semiconductor chip 104 may be a non-volatile memory such as a flash memory, a phase-change random access memory (PRAM), a magnetic random access memory (MRAM), a ferroelectric random access memory (FeRAM), or a resistive random access memory (RRAM).

A fifth passivation layer 405 may be formed on the upper surface of the second semiconductor chip 102. A sixth passivation layer 406 may be formed on the lower surface of the third semiconductor chip 103. A seventh passivation layer 407 may be formed on the upper surface of the third semiconductor chip 103. An eighth passivation layer 408 may be formed on the lower surface of the fourth semiconductor chip 104. Each of the fifth to eighth passivation films 405, 406, 407, and 408 may be the solder resist. However, the technical idea of the present disclosure is not limited thereto.

A first upper chip pad 191 may be disposed on the upper surface of the second semiconductor chip 102. A third chip pad 173 may be disposed on the lower surface of the third semiconductor chip 103. A second upper chip pad 192 may be disposed on the upper surface of the third semiconductor chip 103. A fourth chip pad 174 may be disposed on the lower surface of the fourth semiconductor chip 104. Each of the first upper chip pad 191, the second upper chip pad 192, the third chip pad 173, and the fourth chip pad 174 may include a conductive material. For example, each of the first upper chip pad 191, the second upper chip pad 192, the third chip pad 173, and the fourth chip pad 174 may include gold (Au), silver (Ag), copper (Cu), nickel (Ni), or aluminum (Al).

A third connection member 183 may be disposed between the first upper chip pad 191 and the third chip pad 173. A fourth connection member 184 may be disposed between the second upper chip pad 192 and the fourth chip pad 174. The third connection member 183 may electrically connect the second semiconductor chip 102 and the third semiconductor chip 103 to each other. The fourth connection member 184 may electrically connect the third semiconductor chip 103 and the fourth semiconductor chip 104 to each other. Each of the third connection member 183 and the fourth connection member 184 may include a conductive material. For example, each of the third connection member 183 and the fourth connection member 184 may include gold (Au), silver (Ag), copper (Cu), nickel (Ni), or aluminum (Al).

The encapsulant 700 may cover all of the upper surface of the substrate 100, the upper surface of the first semiconductor chip 101, the upper surface of the second semiconductor chip 102, the upper surface of the third semiconductor chip 103, and the upper surface of the fourth semiconductor chip 104.

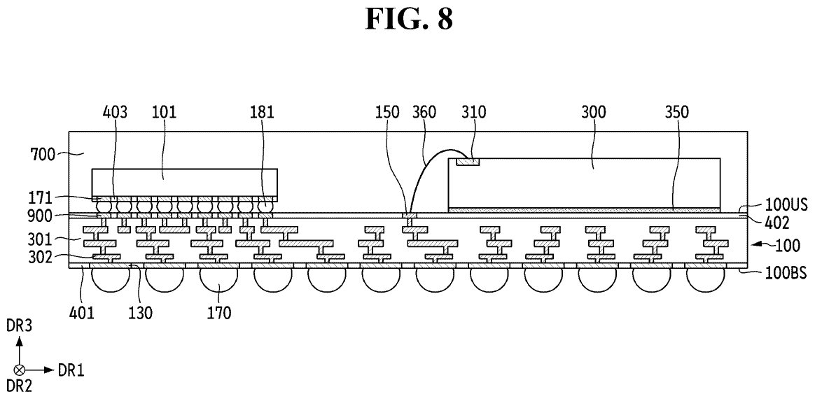

FIG. 8 is a cross-sectional view of a semiconductor package according to still yet another embodiment of the present disclosure. For convenience of description, following description will be made based on differences thereof from those as described above with reference to FIG. 5.

Referring to FIG. 8, a semiconductor package according to still yet another embodiment may include the substrate 100, the first semiconductor chip 101, the second semiconductor chip 300, and the encapsulant 700. For reference, the first semiconductor chip 101 may correspond to the first semiconductor chip 101 of FIG. 5. In addition, the first substrate pad 900 may correspond to the substrate pad 900 of FIG. 5.

The first substrate pad 900 and the second substrate pad 150 may be disposed on the upper surface 100US of the substrate. The second substrate pad 150 may provide a power signal or a ground signal to a second semiconductor chip 300. The second substrate pad 150 may be connected to the external connection terminal 170 via a metal wiring layer 302.

The second semiconductor chip 300 may be disposed on the substrate 100. The second semiconductor chip 300 may be spaced apart from the first semiconductor chip 101 in the first direction DR1. The second semiconductor chip 300 may be disposed on the upper surface 100US of the substrate. The second semiconductor chip 300 may be wire-bonded onto the substrate 100. The second semiconductor chip 300 may be electrically connected to the substrate 100 via a wire 360.

The second semiconductor chip 300 may be of the same type of the semiconductor chip as a type of the first semiconductor chip 101. However, the present disclosure is not limited thereto. In another example, the second semiconductor chip 300 may be a memory semiconductor chip. The memory semiconductor chip may be, for example, a volatile memory such as a dynamic random access memory (DRAM) or a static random access memory (SRAM). Alternatively, the memory semiconductor chip included in the second semiconductor chip 300 may be a non-volatile memory such as a flash memory, a phase-change random access memory (PRAM), a magnetic random access memory (MRAM), a ferroelectric random access memory (FeRAM), or a resistive random access memory (RRAM).

The second semiconductor chip 300 may include an adhesive layer 350. The adhesive layer 350 may be disposed on the lower surface of the second semiconductor chip 300. The adhesive layer 350 may cover the lower surface of the second semiconductor chip 300. The adhesive layer 350 may be disposed between the second semiconductor chip 300 and the substrate 100. The adhesive layer 350 may include a non-conductive Film (NCF), a non-conductive paste (NCP), an insulating polymer, or an epoxy resin. However, the technical idea of the present disclosure is not limited thereto.

The second semiconductor chip 300 may include a chip pad 310. The chip pad 310 may be, for example, one of a power/ground pad and a signal pad. The second semiconductor chip 300 may be electrically connected to the substrate 100 via the chip pad 310. Specifically, the second semiconductor chip 300 may be electrically connected to the substrate 100 via the chip pad 310, the wire 360, and the second substrate pad 150.

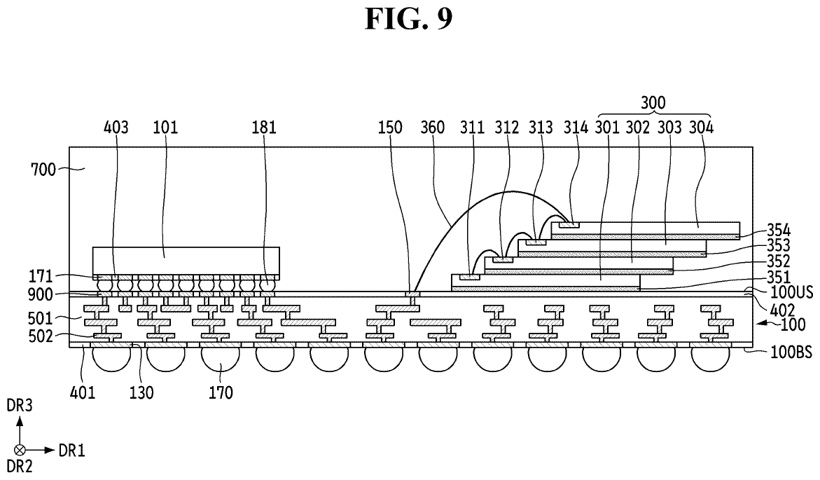

FIG. 9 is a cross-sectional view of a semiconductor package according to still yet another embodiment of the present disclosure. For convenience of description, a description will be made based on differences thereof from those as described above with reference to FIG. 8.

Referring to FIG. 9, the semiconductor package according to some further embodiments may include the substrate 100, the plurality of connection members 181, the first semiconductor chip 101, a memory chip structure 300, and the encapsulant 700.

The substrate 100 may include an insulating layer 501, a metal wiring layer 502, the bonding pad 130, the external connection terminal 170, the first substrate pad 900, the first passivation film 401, the second passivation film 402, and the encapsulant 700. For reference, the insulating layer 501 may correspond to the insulating layer 301 of FIG. 5, and the metal wiring layer 502 may correspond to the metal wiring layer 302 of FIG. 5.

The memory chip structure 300 may include the first to fourth memory chips 301 to 304 stacked sequentially. The first to fourth memory chips 301 to 304 may be stacked in a stepwise manner. The first to fourth memory chips 301 to 304 may be stacked in an ascending stepwise manner in the first direction DR1.

The first memory chip 301 may be disposed on the substrate 100. The first memory chip 301 may include a first adhesive layer 351 on a lower surface thereof. The first memory chip 301 may include a first pad 311 on an upper surface thereof. The first pad 311 may correspond to the chip pad 310 as described above with reference to FIG. 8.

The second memory chip 302 may be disposed on the first memory chip 301. The second memory chip 302 may include a second adhesive layer 352 on a lower surface thereof. The second memory chip 302 may include a second pad 312 on an upper surface thereof. The second pad 312 may correspond to the chip pad 310 as described above with reference to FIG. 8.

The third memory chip 303 may be disposed on the second memory chip 302. The third memory chip 303 may include a third adhesive layer 353 on a lower surface thereof. The third memory chip 303 may include a third pad 313 on an upper surface thereof. The third pad 313 may correspond to the chip pad 310 as described above with reference to FIG. 8.

The fourth memory chip 304 may be disposed on the third memory chip 303. The fourth memory chip 304 may include a fourth adhesive layer 354 on a lower surface thereof. The fourth memory chip 304 may include a fourth pad 314 on an upper surface thereof. The fourth pad 314 may correspond to the chip pad 310 as described above with reference to FIG. 8.

Although FIG. 9 illustrates that the second pad 312 of the second memory chip 302 is connected to the first pad 311 of the first memory chip 301 via a wire, an embodiment of the present disclosure is not limited thereto. For example, the second pad 312 of the second memory chip 302 may be connected to the second substrate pad 150 disposed on the substrate 100 via a wire.

Although FIG. 9 illustrates that the third pad 313 of the third memory chip 303 is connected to the second pad 312 of the second memory chip 302 via a wire, an embodiment of the present disclosure is not limited thereto. For example, the third pad 313 of the third memory chip 303 may be connected to the second substrate pad 150 disposed on the substrate 100 via a wire. In another example, the third pad 313 of the third memory chip 303 may be connected to the first pad 311 of the first memory chip 301 via a wire.

Although FIG. 9 illustrates that the fourth pad 314 of the fourth memory chip 304 is connected to the third pad 313 of the third memory chip 303 via a wire, an embodiment of the present disclosure is not limited thereto. For example, the fourth pad 314 of the fourth memory chip 304 may be connected to the second substrate pad 150 disposed on the substrate 100 via a wire. In another example, the fourth pad 314 of the fourth memory chip 304 may be connected to the first pad 311 of the first memory chip 301 via a wire. In still another example, the fourth pad 314 of the fourth memory chip 304 may be connected to the second pad 312 of the second memory chip 302 via a wire.

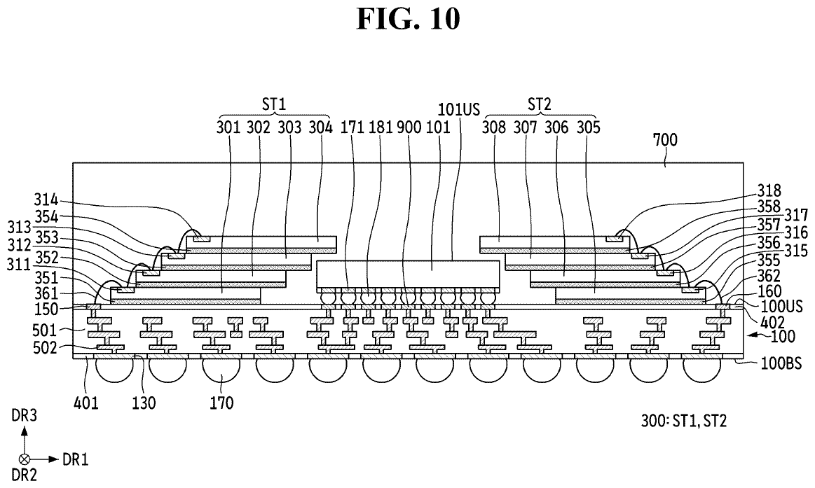

FIG. 10 is a cross-sectional view of a semiconductor package according to still yet another embodiment of the present disclosure. For convenience of description, a description will be made based on differences thereof from those as described above with reference to FIG. 9.

Referring to FIG. 10, the semiconductor package according to some further embodiments may include the substrate 100, the plurality of connection members 181, the first semiconductor chip 101, the memory chip structure 300, and the encapsulant 700.

The substrate 100 may include the insulating layer 501, the metal wiring layer 502, the bonding pad 130, the external connection terminal 170, the first substrate pad 900, the second substrate pad 150, a third substrate pad 160, the first passivation film 401, and the second passivation film 402. For reference, the insulating layer 501 may correspond to the insulating layer 301 of FIG. 5, and the metal wiring layer 502 may correspond to the metal wiring layer 302 of FIG. 5.

The first substrate pad 900, the second substrate pad 150, and the third substrate pad 160 may be disposed on the upper surface 100US of the substrate. The second substrate pad 150 may provide a power signal or a ground signal to a first chip stack ST1. The third substrate pad 160 may provide a power signal or a ground signal to a second chip stack ST 2. The second substrate pad 150 may be connected to the external connection terminal 170 via the metal wiring layer 502. The third substrate pad 160 may be connected to the external connection terminal 170 via the metal wiring layer 502.

The first semiconductor chip 101 may be disposed between the first chip stack ST1 and the second chip stack ST2. The first chip stack ST1 and the second chip stack ST2 may be spaced apart from each other in the first direction DR1 while the first semiconductor chip 101 is interposed therebetween.

The memory chip structure 300 may include the first chip stack ST1 and the second chip stack ST2. The first chip stack ST1 may include the first to fourth memory chips 301 to 304 stacked sequentially. The first to fourth memory chips 301 to 304 may be stacked in an ascending stepwise manner in the first direction DR1. The second chip stack ST2 may include fifth to eighth memory chips 305 to 308 stacked sequentially. The fifth to eighth memory chips 305 to 308 may be stacked in a descending stepwise manner along the first direction DR 1.

The first to fourth memory chips 301 to 304 may include the first to fourth pads 311 to 314, respectively. The first to fourth memory chips 301 to 304 may be stacked in an ascending stepwise manner in the first direction DR1. The fifth to eighth memory chips 305 to 308 may include fifth to eighth pads 315 to 318, respectively. The fifth to eighth memory chips 305 to 308 may be stacked in a descending stepwise manner along the first direction DR 1.

The fifth memory chip 305 may be disposed on the substrate 100. The fifth memory chip 305 may include a third adhesive layer 355 on a lower surface thereof. The fifth memory chip 305 may include a fifth pad 315 on an upper surface thereof. The fifth pad 315 may correspond to the chip pad 310 as described above with reference to FIG. 8.

The sixth memory chip 306 may be disposed on the fifth memory chip 305. The sixth memory chip 306 may include a sixth adhesive layer 356 on a lower surface thereof. The sixth memory chip 306 may include a sixth pad 316 on an upper surface thereof. The sixth pad 316 may correspond to the chip pad 310 as described above with reference to FIG. 8.

The seventh memory chip 307 may be disposed on the sixth memory chip 306. The seventh memory chip 307 may include a seventh adhesive layer 357 on a lower surface thereof. The seventh memory chip 307 may include a seventh pad 317 on an upper surface thereof. The seventh pad 317 may correspond to the chip pad 310 as described above with reference to FIG. 8.

The eighth memory chip 308 may be disposed on the seventh memory chip 307. The eighth memory chip 308 may include an eighth adhesive layer 358 on a lower surface thereof. The eighth memory chip 308 may include an eighth pad 318 on an upper surface thereof. The eighth pad 318 may correspond to the chip pad 310 as described above with reference to FIG. 8.

In FIG. 10, the sixth pad 316 of the sixth memory chip 306 is illustrated as being connected to the fifth pad 315 of the fifth memory chip 305 via a wire. However, an embodiment of the present disclosure is not limited thereto. For example, the sixth pad 316 of the sixth memory chip 306 may be connected to the third substrate pad 160 disposed on the substrate 100 via a wire.

Although FIG. 10 illustrates that the seventh pad 317 of the seventh memory chip 307 is connected to the sixth pad 316 of the sixth memory chip 306 via a wire, an embodiment of the present disclosure is not limited thereto. For example, the seventh pad 317 of the seventh memory chip 307 may be connected to the third substrate pad 160 disposed on the substrate 100 via a wire.

Although FIG. 10 illustrates that the eighth pad 318 of the eighth memory chip 308 is connected to the seventh pad 317 of the seventh memory chip 307 via a wire, an embodiment of the present disclosure is not limited thereto. For example, the eighth pad 318 of the eighth memory chip 308 may be connected to the third substrate pad 160 disposed on the substrate 100 via a wire.

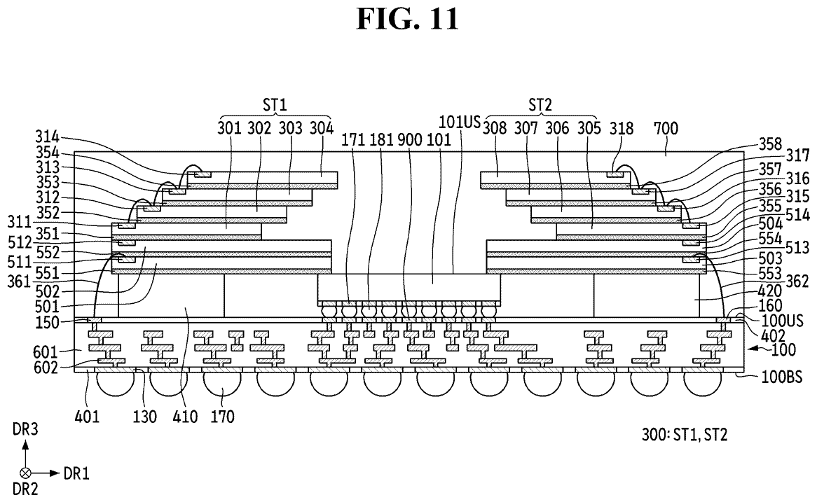

FIG. 11 is a cross-sectional view of a semiconductor package according to still yet another embodiment of the present disclosure. For convenience of description, a description will be made based on differences thereof from those as described above with reference to FIG. 10.

Referring to FIG. 11, the semiconductor package according to some embodiments may include the substrate 100, a first dummy chip 410, a second dummy chip 420, the plurality of connection members 181, the first semiconductor chip 101, a second semiconductor chip 501, a third semiconductor chip 502, a fourth semiconductor chip 503, a fifth semiconductor chip 504, the memory chip structure 300, and the encapsulant 700.

The substrate 100 may include an insulating layer 601, a metal wiring layer 602, the bonding pad 130, the external connection terminal 170, the first substrate pad 900, the first passivation film 401, the second passivation film 402, and an encapsulant 700. For reference, the insulating layer 601 may correspond to the insulating layer 301 of FIG. 5, and the metal wiring layer 602 may correspond to the metal wiring layer 302 of FIG. 5.

The first semiconductor chip 101 may be disposed between the first dummy chip 410 and the second dummy chip 420. An upper surface of the first dummy chip 410 and an upper surface of the second dummy chip 420 may be coplanar with the upper surface 101US of the first semiconductor chip 101. However, an embodiment of the present disclosure is not limited thereto. For example, based on the upper surface 100US of the substrate, a vertical level of each of the upper surface of the first dummy chip 410 and the upper surface of the second dummy chip 420 may be higher than a vertical level of the upper surface 101US of the first semiconductor chip 101.

Each of the first dummy chip 410 and the second dummy chip 420 may include silicon. The vertical levels of the first dummy chip 410 and the second dummy chip 420 may coincide with the vertical level of the first semiconductor chip 101 such that the first chip stack ST1, the second chip stack ST2, the second semiconductor chip 501, the third semiconductor chip 502, the fourth semiconductor chip 503, and the fifth semiconductor chip 504 are stably stacked thereon.

The second semiconductor chip 501 and the third semiconductor chip 502 may be stacked on the first dummy chip 410 and the first semiconductor chip 101. The second semiconductor chip 501 and the third semiconductor chip 502 may be disposed under the first chip stack ST1.

The fourth semiconductor chip 503 and the fifth semiconductor chip 504 may be stacked on the second dummy chip 420 and the first semiconductor chip 101. The fourth semiconductor chip 503 and the fifth semiconductor chip 504 may be disposed under the second chip stack ST 2. Each of the second semiconductor chip 501, the third semiconductor chip 502, the fourth semiconductor chip 503, and the fifth semiconductor chip 504 may include each of adhesive layers 551 to 554 on each of lower surfaces thereof.

Each of the adhesive layers 551 to 554 may cover the lower surface of the memory chip structure 300. The adhesive layers 551 to 554 may be disposed between the memory chip structure 300 and the substrate 100. Each of the adhesive layers 551 to 554 may include a non-conductive film (NCF), a non-conductive paste (NCP), an insulating polymer, or an epoxy resin. However, the technical idea of the present disclosure is not limited thereto.

Each of the second semiconductor chip 501, the third semiconductor chip 502, the fourth semiconductor chip 503, and the fifth semiconductor chip 504 may be a memory semiconductor chip. Each of the second semiconductor chip 501, the third semiconductor chip 502, the fourth semiconductor chip 503, and the fifth semiconductor chip 504 may be a volatile memory such as dynamic random access memory (DRAM) or static random access memory (SRAM). Alternatively, each of the second semiconductor chip 501, the third semiconductor chip 502, the fourth semiconductor chip 503, and the fifth semiconductor chip 504 may include a non-volatile memory such as a flash memory, a phase-change random access memory (PRAM), a magnetic random access memory (MRAM), a ferroelectric random access memory (FeRAM), a resistive random access memory (RRAM), or the like.

Each of the second semiconductor chip 501, the third semiconductor chip 502, the fourth semiconductor chip 503, and the fifth semiconductor chip 504 may include a different type of a memory from that of each of the first memory chip to the fourth memory chip 301 to 304 of the first chip stack ST1 and the fifth memory chip to the eighth memory chip 305 to 308 of the second chip stack ST2. For example, each of the first to fourth memory chips 301 to 304 of the first chip stack ST1 and the fifth to eighth memory chips 305 to 308 of the second chip stack ST2 may include a flash memory, while each of the second semiconductor chip 501, the third semiconductor chip 502, the fourth semiconductor chip 503, and the fifth semiconductor chip 504 may include DRAM.

The second semiconductor chip 501 may include a ninth pad 511. The third semiconductor chip 502 may include a tenth pad 512. The ninth pad 511 of the second semiconductor chip 501 may be connected to the first substrate pad 150 via a first wire 361.

The fourth semiconductor chip 503 may include an eleventh pad 513. The fifth semiconductor chip 502 may include a twelfth pad 514. The eleventh pad 513 of the fourth semiconductor chip 503 may be connected to the second substrate pad 160 via a second wire 362.

For example, the second semiconductor chip 501 may be connected to the external connection terminal 170 via the ninth pad 511 and the second substrate pad 150 connected to each other via the first wire 361. For example, the second semiconductor chip 501 may receive an input signal from the external connection terminal 170 via the ninth pad 511 and the second substrate pad 150.

For example, the fourth semiconductor chip 503 may be connected to the external connection terminal 170 via the eleventh pad 513 and the third substrate pad 160 connected to each other via the second wire 362. For example, the fourth semiconductor chip 503 may receive an input signal from the external connection terminal 170 via the eleventh pad 513 and the third substrate pad 160.

FIG. 11 illustrates that a stack of the second semiconductor chip 501 and the third semiconductor chip 502 and a stack of the fourth semiconductor chip 503 and the fifth semiconductor chip 504 have the same width and the same vertical level. However, embodiments of the present disclosure are not limited thereto. For example, the second semiconductor chip 501 and the third semiconductor chip 502 may be stacked in a stepped shape, and the fourth semiconductor chip 503 and the fifth semiconductor chip 504 may be stacked in a stepped shape.

Although embodiments of the present disclosure have been described above with reference to the accompanying drawings, the present disclosure may not be limited to embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that embodiments as described above are not restrictive but illustrative in all respects.

What is claimed is:

1. A semiconductor package comprising:
a substrate;
a first pad array disposed on the substrate and including a plurality of pads repeatedly arranged in a first direction in a plan view of the semiconductor package; and
a second pad array disposed on the substrate and spaced apart from the first pad array in a second direction perpendicular to the first direction in the plan view, wherein the second pad array includes a plurality of pads repeatedly arranged in the first direction in the plan view,
wherein the plurality of pads of the first pad array include first pads and second pads alternately arranged with each other,
wherein the plurality of pads of the second pad array include third pads and fourth pads alternately arranged with each other,
wherein a width in the first direction of one of the first pads is different from a width in the first direction of one of the second pads,
wherein a width in the first direction of one of the third pads is different from a width in the first direction of one of the fourth pads.

2. The semiconductor package of claim 1, wherein the width in the first direction of the one of the first pads is greater than the width in the first direction of the one of the second pads,
wherein a width in the second direction of the one of the first pads is smaller than a width in the second direction of the one of the second pads.

3. The semiconductor package of claim 2, wherein the width in the first direction of the one of the third pads is smaller than the width in the first direction of the one of the fourth pads,
wherein a width in the second direction of the one of the third pads is greater than a width in the second direction of the one of the fourth pads.

4. The semiconductor package of claim 1, wherein center points of the first pads are aligned, in the first direction, with respective center points of the third pads along a same line extending in the second direction,
wherein center points of the second pads are aligned, in the first direction, with respective center points of the fourth pads along a same line extending in the second direction.

5. The semiconductor package of claim 4, wherein the width in the first direction of one of the first pads is substantially equal to the width in the second direction of one of the third pads,
wherein the width in the first direction of one of the second pads is substantially equal to the width in the second direction of one of the fourth pads.

6. The semiconductor package of claim 4, wherein the width in the first direction of one of the first pads is substantially equal to the width in the first direction of one of the fourth pads,
wherein the width in the first direction of one of the second pads is substantially equal to the width in the second direction of one of the third pads.

7. The semiconductor package of claim 1, wherein a center point of one of the first pads is positioned between, with respect to the first direction, a center point of one of the third pads and a center point of one of the fourth pads.

8. The semiconductor package of claim 1, wherein center points of the first pads and are aligned, in the second direction, with center points of the second pads along a same line extending in the first direction,
wherein center points of the third pads are aligned, in the second direction, with center points of the fourth pads along a same line extending in the first direction.

9. The semiconductor package of claim 1, further comprising a third pad array and a fourth pad array disposed on the substrate and spaced apart from the first pad array and the second pad array in the second direction,
wherein the third pad array is disposed between the second pad array and the fourth pad array,
wherein the third pad array includes fifth pads and sixth pads alternately arranged with each other in the first direction in the plan view,
wherein the fourth pad array includes seventh pads and eighth pads alternately arranged with each other in the first direction in the plan view.

10. The semiconductor package of claim 1, wherein each of the first pads and the second pads includes at least one of gold (Au), silver (Ag), copper (Cu), nickel (Ni), or aluminum (Al).

11. A semiconductor package comprising:
a substrate;
a first pad array disposed on the substrate and including a plurality of first pads repeatedly arranged in a first direction in a plan view of the semiconductor package; and
a second pad array disposed on the substrate and spaced apart from the first pad array in a second direction perpendicular to the first direction in the plan view, wherein the second pad array includes a plurality of second pads repeatedly arranged in the first direction in the plan view,
wherein a width in the first direction of each of the plurality of first pads is greater than a width in the first direction of any one of the second pads,
wherein a width in the second direction of each of the plurality of first pads is smaller than a width in the second direction of any one of the second pads.

12. The semiconductor package of claim 11, wherein center points of the first pads are aligned, in the first direction, with respective center points of the second pads along a same line extending in the second direction.

13. The semiconductor package of claim 11, wherein a center point of one of the first pads is disposed between, with respect to the first direction, center points of two adjacent ones of the second pads.

14. The semiconductor package of claim 11, wherein the width in the first direction of any one of the first pads is substantially equal to the width in the second direction of any one of the second pads,
wherein the width in the second direction of each of the plurality of first pads is substantially equal to the width in the first direction of any one of the second pads.

15. The semiconductor package of claim 11, wherein each of the first pads and the second pads includes at least one of gold (Au), silver (Ag), copper (Cu), nickel (Ni), or aluminum (Al).

16. The semiconductor package of claim 11, further comprising a third pad array and a fourth pad array sequentially arranged from the first pad array and the second pad array in the second direction,
wherein the third pad array includes a plurality of third pads repeatedly arranged in the first direction in the plan view,
wherein the fourth pad array includes a plurality of fourth pads repeatedly arranged in the first direction in the plan view.

17. A semiconductor package comprising:
a package substrate including a wiring structure and including upper and lower surfaces opposite to each other;
an external connection terminal disposed on the lower surface of the package substrate;
a semiconductor chip flip-chip bonded to the upper surface of the package substrate;
a substrate pad disposed on the upper surface of the package substrate;
a chip pad disposed on a lower surface of the semiconductor chip; and
a connection member disposed between the substrate pad and the chip pad,
wherein the substrate pad includes:
a first pad array including a plurality of pads repeatedly arranged in a first direction in a plan view of the semiconductor package; and
a second pad array spaced apart from the first pad array in a second direction perpendicular to the first direction in the plan view and including a plurality of pads repeatedly arranged in the first direction in the plan view,
wherein the plurality of pads of the first pad array include first pads and second pads alternately arranged with each other,
wherein the plurality of pads of the second pad array include third pads and fourth pads alternately arranged with each other,
wherein a width in the first direction of one of the first pads is different from a width in the first direction of one of the second pads,
wherein a width in the first direction of one of the third pads is different from a width in the first direction of one of the fourth pads.

18. The semiconductor package of claim 17, wherein the width in the first direction of the one of the first pads is greater than the width in the first direction of the one of the second pads,
wherein a width in the second direction of the one of the first pads is smaller than a width in the second direction of the one of the second pads.

19. The semiconductor package of claim 17, wherein center points of the first pads are aligned, in the first direction, with respective center points of the third pads along a same line extending in the second direction,
wherein center points of the second pads are aligned, in the first direction, with respective center points of the fourth pads along a same line extending in the second direction.

20. The semiconductor package of claim 17, wherein a center point of one of the first pads is positioned between, with respect to the first direction, a center point of one of the third pads and a center point of one of the fourth pads.
